(19) United States
(12) Patent Application Publication
(10) Pub. No.: US 2015/0017450 A1
(43) Pub. Date: Jan. 15, 2015

(54) RESIN COMPOSITION AND SEMICONDUCTOR MOUNTING SUBSTRATE OBTAINED BY MOLDING SAME

(71) Applicant: TORAY INDUSTRIES, INC., Tokyo (JP)

(72) Inventors: Hideki Oka, Nagoya-shi (JP); Nobuyuki Tomioka, Nagoya-shi (JP); Shiro Honda, Nagoya-shi (JP)

(21) Appl. No.: 14/374,643

(22) PCT Filed: Jan. 21, 2013
(86) PCT No.: PCT/JP2013/051068

§ 371 Date: Jul. 25, 2014

(30) Foreign Application Priority Data
Jan. 26, 2012 (JP) 2012-014301
Jul. 9, 2012 (JP) 2012-153487

(51) Int. Cl. C08L 63/00; C08K 3/36; H01L 23/29; C08K 5/5435

(52) U.S. Cl. CPC C08L 63/00; C08K 5/5435; C08K 3/36; H01L 23/293; C08L 2205/025; C08L 2203/20; C08L 2201/02
USPC 428/418; 523/466; 523/428; 523/440

(57) ABSTRACT

A resin composition which contains at least constituent elements (A)-(E) described below and wherein the epoxy resin (A) contains 80-100% by mass of a bifunctional epoxy resin and component (D) is contained in an amount of 60-85% by mass relative to 100% by mass of the total mass of the resin composition. This resin composition does not substantially contain a solvent and is in a liquid state at room temperature. (A) an epoxy rein (B) an amine-based curing agent (C) an accelerator that has at least one functional group selected from among a dimethylureide group, an imidazole group and a tertiary amino group (D) silica particles (E) a silane coupling agent Provided is a resin composition which has excellent curability at low temperatures and a sufficiently low linear expansion coefficient after curing. This resin composition does not suffer from warping in cases where applied to a copper thin film and molded, and does not suffer from separation or cracks even if a substrate obtained therefrom is bent. Also provided is a semiconductor mounting substrate which is obtained by molding the resin composition.

### TECHNICAL FIELD

The present invention relates to a resin composition suitably used for a semiconductor packaging substrate, and further relates to a semiconductor packaging substrate produced by molding the same.

### BACKGROUND ART

Along with a recent reduction in size, reduction in weight, and increase in performance of electrical equipment, there has been a demand for improved packaging density of electronic parts on a printed circuit board, and the mainstream method of packaging a semiconductor has shifted from pin insertion to surface mounting. In particular, flip-chip mounting has received attention as a method that is particularly capable of enhancing packaging density.

### PRIOR ART DOCUMENTS

### Patent Documents

Flip-chip mounting is a method in which semiconductor chips are collectively connected on the circuit pattern side of a circuit substrate via a plurality of projections called bumps, and after mounting, underfill material for insulation is poured between the semiconductor chips and the circuit substrate and cured for completion. As an application of this method, a dam material composition has been reported which makes underfill material being poured into gap, for example, between devices not to overflow from a circuit substrate when semiconductor chips having a multilayer structure are encapsulated (Patent Document 1).

On the other hand, if the substrate itself is made of a resin material on which copper bumps are preliminarily formed, insulation of underfill material is unnecessary, which promises a dramatic improvement in productivity. However, in the attempt to produce such a substrate with the composition for underfill material mentioned above or the dam composition disclosed in Patent Document 1, there have been problems in that since the linear expansion coefficient of a cured resin product is significantly higher than that of copper, large warpage occurs during curing, and that since the adhesive strength and elongation of the cured resin product are poor, peeling at the interface between copper and the resin or cracking of the resin occurs when a substrate obtained therefrom is bent. A sheet-like resin composition for encapsulating an electron device having improved flame resistance, a cured product of which has improved warpage and distortion, has been reported (Patent Document 2).

Further, a resin composition used for semiconductor encapsulation application, in which a phenol resin is used as a curing agent to improve fluidity, curing properties, moldability, and solder resistance, has been reported (Patent Document 3).

Further, in the field of fiber-reinforced composite materials, an epoxy resin composition comprising a curing accelerator having high curing reactivity at low temperatures has been reported (Patent Document 4).

Further, a resin composition for interlayer insulation of a multilayer printed circuit board, in which an inorganic filler is added to lower the coefficient of thermal expansion, has been reported (Patent Document 5).

In addition, to resins for applications related to electronic parts such as semiconductor packaging substrates, phosphate esters and the like have been added as a flame retardant in view of safety from fire to provide flame resistance and self-extinguishing properties. Specifically, for example, addition of a phosphate ester compound containing a specific amino group has been proposed (Patent Document 6).

Patent Document 1: JP 2011-14885 A

Patent Document 2: JP 2011-246596 A

Patent Document 3: JP 2006-143784 A

Patent Document 4: JP 2003-128764 A

Patent Document 5: JP 2011-140652 A

Patent Document 6: JP 2009-292895 A

### SUMMARY OF THE INVENTION

### Problems to be Solved by the Invention

However, in the method of Patent Document 1, heat is applied in the reflow of semiconductor chips, and after underfill material injection, heat needs to be applied again, leading to a complicated production process and low productivity.

The resin composition of Patent Document 2 comprises a polyfunctional epoxy resin in large amounts, and the elongation of a cured resin product is poor. Thus, there has been a problem in that peeling at the interface between copper and the resin or cracking of the resin occurs.

The resin composition of Patent Document 3 requires a high temperature for curing and shrinks significantly during curing. As a result, in the attempt to produce such a substrate, the substrate after molding caused warpage, leading to difficulty in application.

The linear expansion coefficient of a cured product of the resin composition of Patent Document 4 is high. As a result, in the attempt to produce such a substrate, there was a tendency that the substrate caused warpage, and many voids occurred during molding due to high viscosity of the resin composition, resulting in a low-quality substrate.

In Patent Document 5, a phenol resin is used as a curing agent. As a result, there was a tendency that a high temperature was required for curing, leading to low productivity, and many voids occurred during molding due to high viscosity of the resin composition, resulting in a low-quality substrate.

The resin composition of Patent Document 6 requires a high temperature for curing and shrinks significantly during curing. As a result, in the attempt to produce such a substrate, the substrate after molding caused warpage, leading to difficulty in application.

As described above, hitherto there has been no resin composition that is capable of solving all the problems described above and can be applied to a semiconductor packaging substrate.

The present invention aims to overcome such disadvantages of the prior art, and to provide a resin composition which has excellent curing properties at low temperatures, has a sufficiently low linear expansion coefficient after being cured, causes no warpage when applied to a copper thin film and molded, and causes no peeling or cracking even if a substrate obtained therefrom is bent, and a semiconductor packaging substrate produced by molding the resin composition.

### Means for Solving the Problems

To solve the problems described above, the resin composition of the present invention has the following constitution, that is, a resin composition, comprising the following components (A) to (E):

(A) an epoxy resin;

(B) an amine curing agent;

(C) an accelerator having at least one functional group selected from dimethylureido group, imidazole group, and tertiary amino group;

(D) silica particles; and

(E) a silane coupling agent,

wherein the epoxy resin (A) comprises 80 to 100% by mass of a bifunctional epoxy resin, and (D) is contained in an amount of 60 to 85% by mass based on 100% by mass of the total amount of the resin composition, the resin composition being substantially free of solvent and liquid at normal temperature.

According to a preferred embodiment of the resin composition of the present invention, the resin composition further comprises (F) a phosphorus-containing flame retardant.

According to a preferred embodiment of the resin composition of the present invention, the epoxy resin (A) comprises an epoxy resin having at least one chemical structure selected from naphthalene structure, biphenyl structure, and dicyclopentadiene structure.

According to a preferred embodiment of the resin composition of the present invention, the amine curing agent (B) is an aliphatic amine curing agent.

According to a preferred embodiment of the resin composition of the present invention, the amine curing agent (B) is dicyandiamide or a derivative thereof.

According to a preferred embodiment of the resin composition of the present invention, the accelerator (C) having at least one functional group selected from dimethylureido group, imidazole group, and tertiary amino group is at least one compound selected from phenyldimethylurea, methylenebis(phenyldimethylurea), tolylenebis(dimethylurea), and halogenated derivatives thereof.

According to a preferred embodiment of the resin composition of the present invention, the accelerator (C) having at least one functional group selected from dimethylureido group, imidazole group, and tertiary amino group is methylenebis(phenyldimethylurea) or tolylenebis(dimethylurea).

According to a preferred embodiment of the resin composition of the present invention, the silica particles (D) comprise a component d₁ with an average particle size of 10 μm to 100 μM and a component d₂ with an average particle size of 0.1 μm or more but less than 10 μm at a mass ratio (d₁/d₂) of 85/15 to 95/5, the average particle size being determined using a laser diffraction particle size analyzer.

According to a preferred embodiment of the resin composition of the present invention, the silane coupling agent (E) is contained in an amount of 0.5 to 2 parts by mass based on 100 parts by mass of the silica particles (D).

According to a preferred embodiment of the resin composition of the present invention, phosphorus components in the resin composition are contained in an amount of 0.5 to 5% by mass in terms of phosphorus atom based on 100% by mass of the total amount of resin components (composed of the epoxy resin (A), the amine curing agent (B), the accelerator (C) having at least one functional group selected from dimethylureido group, imidazole group, and tertiary amino group, and the phosphorus-containing flame retardant (F)) in the resin composition.

According to a preferred embodiment of the resin composition of the present invention, the phosphorus-containing flame retardant (F) is selected from phosphazene derivatives and condensed phosphate esters.

Further, in the present invention, the resin composition described above can be molded into a molded product, preferably, a semiconductor packaging substrate produced by applying the resin composition described above to a metal sheet and curing the metal sheet.

### Effects of the Invention

The present invention provides a semiconductor packaging substrate which causes no warpage when molded and, further, causes no peeling or cracking even if it is bent, and a resin composition suitably used for the semiconductor packaging substrate. Further, if a phosphorus-containing flame retardant is added to the resin composition, a cured product thereof has high flame resistance even if it is a thin molded body.

### BEST MODE FOR CARRYING OUT THE INVENTION

The resin composition of the present invention and a semiconductor packaging substrate produced by molding the same will now be described in detail.

First, the resin composition according to the present invention will be described.

The component (A) in the present invention is an epoxy resin. The epoxy resin means a compound having two or more epoxy groups in one molecule.

Specific examples of the component (A) in the present invention include aromatic glycidyl ethers obtained from a phenol having a plurality of hydroxyl groups, aliphatic glycidyl ethers obtained from an alcohol having a plurality of hydroxyl groups, glycidyl amines obtained from an amine, glycidyl esters obtained from a carboxylic acid having a plurality of carboxyl groups, epoxy resins having an oxirane ring, and phosphorus-containing epoxy resins.

Examples of aromatic glycidyl ethers that can be used as the component (A) in the present invention include diglycidyl ethers obtained from a bisphenol such as diglycidyl ether of bisphenol A, diglycidyl ether of bisphenol F, diglycidyl ether of bisphenol AD, and diglycidyl ether of bisphenol S; polyglycidyl ethers of novolac obtained from a phenol and an alkyl phenol; diglycidyl ether of resorcinol; diglycidyl ether of hydroquinone; diglycidyl ether of 4,4′-dihydroxybiphenyl; diglycidyl ether of 4,4′-dihydroxy-3,3′,5,5′-tetramethylbiphenyl; diglycidyl ether of 1,6-dihydroxynaphthalene; diglycidyl ether of 9,9′-bis(4-hydroxyphenyl)fluorene; triglycidyl ether of tris(p-hydroxyphenyl)methane; tetraglycidyl ether of tetrakis(p-hydroxyphenyl)ethane; and diglycidyl ether having an oxazolidone backbone obtained by reacting diglycidyl ether of bisphenol A with bifunctional isocyanate.

Examples of aliphatic glycidyl ethers that can be used as the component (A) in the present invention include diglycidyl ether of ethylene glycol, diglycidyl ether of propylene glycol, diglycidyl ether of 1,4-butanediol, diglycidyl ether of 1,6-hexanediol, diglycidyl ether of neopentyl glycol, diglycidyl ether of cyclohexanedimethanol, diglycidyl ether of glycerin, triglycidyl ether of glycerin, diglycidyl ether of trimethylolethane, triglycidyl ether of trimethylolethane, diglycidyl ether of trimethylolpropane, triglycidyl ether of trimethylolpropane, tetraglycidyl ether of pentaerythritol, diglycidyl ether of dodecahydro bisphenol A, and diglycidyl ether dodecahydro bisphenol F.

Examples of glycidyl amines that can be used as the component (A) in the present invention include diglycidyl aniline, diglycidyl toluidine, triglycidyl aminophenol, tetraglycidyl diaminodiphenylmethane, tetraglycidyl xylylenediamine, and halogen-substituted products, alkyl-substituted products, and hydrogenated products thereof.

Examples of epoxy resins having an oxirane ring that can be used as the component (A) in the present invention include vinylcyclohexene dioxide, dipentene dioxide, 3,4-epoxycyclohexylmethyl 3,4-epoxycyclohexane carboxylate, bis(3,4-epoxycyclohexylmethyl) adipate, dicyclopentadiene dioxide, bis(2,3-epoxycyclopentyl) ether, and oligomer of 4-vinylcyclohexene dioxide.

Examples of glycidyl esters of glycidyl ester type epoxy resins that can be used as the component (A) in the present invention include phthalic acid diglycidyl ester, terephthalic acid diglycidyl ester, hexahydrophthalic acid diglycidyl ester, and dimer acid diglycidyl ester.

Examples of phosphorus-containing epoxy resins that can be used as the component (A) in the present invention include an epoxy resin obtained from dichlorophenylphosphine oxide and glycidol, an epoxy resin obtained from dichlorophenoxyphosphine oxide and glycidol, an epoxy resin obtained from diglycidyl ether of bisphenol A and 2-(6-oxido-6H-dibenz<c,e>oxaphosphorin-6-yl)-1,4-benzenediol (ODOPB), an epoxy resin obtained from a phenol novolac epoxy resin and 9,10-dihydro-9-oxa-10-phosphaphenanthrene-10-oxide (DOPO), an epoxy resin obtained from diglycidyl ether of bisphenol A and DOPO, and an epoxy resin obtained from diglycidyl ether of 1,6-dihydroxynaphthalene and ODOPB. Adding a phosphorus-containing epoxy resin as the component (A) provides the composition with flame resistance. When the phosphorus-containing epoxy resin is added for the purpose of providing flame resistance, the amount thereof is preferably such that phosphorus components are contained in an amount of 0.5 to 5% by mass in terms of phosphorus atom, more preferably 1.5 to 4% by mass, based on 100% by mass of the total amount of the components (A), (B), (C), and (F).

The bifunctional epoxy resin in the present invention is an epoxy resin having two epoxy groups in one molecule. Such a bifunctional epoxy resin, as compared to polyfunctional epoxy resins having three or more epoxy groups in one molecule, has a low crosslink density when cured, leading to loose binding of molecular structure, and therefore provides a cured resin product having high elongation. As a result, there is an advantage in that even if a substrate formed by applying the resin composition of the present invention to a copper sheet is bent, the resin closely adheres to the copper sheet without causing cracking, which enables continuous production by a roll-to-roll process.

The component (A) in the present invention comprises 80 to 100% by mass of a bifunctional epoxy resin. When the amount of the bifunctional epoxy resin in the component (A) is less than 80% by mass, a cured resin product is not provided with sufficient elongation, and the resin can cause cracking when a substrate is bent.

The component (A) in the present invention preferably comprises an epoxy resin having at least one chemical structure selected from naphthalene structure, biphenyl structure, and dicyclopentadiene structure. The naphthalene structure, biphenyl structure, and dicyclopentadiene structure are rigid structure, and thus have the effect of increasing heat resistance as well as the effect of reducing a linear expansion coefficient to a low level, offering an advantage in that a molded substrate is less likely to cause warpage.

The epoxy resin having at least one chemical structure selected from naphthalene structure, biphenyl structure, and dicyclopentadiene structure is preferably contained in an amount of 20 to 100 parts by mass, more preferably 40 to 100 parts by mass, and still more preferably 50 to 100 parts by mass in 100% by mass of the component (A).

Among the epoxy resins having at least one chemical structure selected from naphthalene structure, biphenyl structure, and dicyclopentadiene structure, an epoxy resin having naphthalene structure is particularly suitably used because the resin composition is provided with lower viscosity and a cured resin product is provided with higher elongation.

Examples of commercially available products of epoxy resins having naphthalene structure include “EPICLON” (registered trademark) HP-4032, HP-4032D, HP-4700, HP-4710 HP-4770 (available from DIC Corporation), and NC-7000 (available from Nippon Kayaku Co., Ltd.).

Examples of commercially available products of epoxy resins having biphenyl structure include “jER” (registered trademark) YX4000H, YX4000, YL6121H (available from Mitsubishi Chemical Corporation), and NC-3000 (available from Nippon Kayaku Co., Ltd.).

Examples of commercially available products of epoxy resins having dicyclopentadiene structure include “EPICLON” (registered trademark) HP-7200, HP-7200L, HP-7200H (available from DIC Corporation), Tactix556 (available from Huntsman Advanced Materials), and XD-1000 (available from Nippon Kayaku Co., Ltd.).

The component (B) in the present invention is an amine curing agent, which refers to a compound having in one molecule at least one amino group that can react with epoxy groups of an epoxy resin, and acts as a curing agent for the epoxy resin. From the standpoint of storage stability and curing properties, the component (B) preferably has a melting point of 80° C. or higher, more preferably 100° C. or higher.

The component (B) in the present invention can be broadly classified into aliphatic amine curing agents which are amine compounds having an amino group directly connected to an aliphatic chain structure or alicyclic structure, and aromatic amine curing agents which are amine compounds having an aromatic ring. Among them, aliphatic amine curing agents having high curing reactivity at low temperatures are suitably used.

Specific examples of such aliphatic amine curing agents include aliphatic polyamines, alicyclic polyamines, and modifications thereof; dicyandiamide and derivatives thereof; and organic acid hydrazides.

Among them, dicyandiamide and derivatives thereof, and organic acid hydrazides are suitably used because they have a high melting point and reduce the compatibility with an epoxy resin in a low-temperature range, providing an excellent pot life. In particular, dicyandiamide and derivatives thereof are suitably used because they provide a cured product with excellent dynamic properties.

Examples of the aromatic amine curing agent that can be used as the component (B) in the present invention include diaminodiphenylmethane (melting point: 89° C.) and diaminodiphenylsulfone (melting point: 175° C.).

Examples of the dicyandiamide and derivatives thereof that can be used as the component (B) in the present invention include dicyandiamide (melting point: 210° C.).

Examples of the organic acid hydrazide that can be used as the component (B) in the present invention include adipic acid dihydrazide (melting point: 180° C.).

The component (B) is preferably contained in an amount of 5 to 35 parts by mass, more preferably 5 to 15 parts by mass, based on 100 parts by mass of the epoxy resin (A). When the amount of the component (B) is in this preferred range, curing reaction sufficiently proceeds, and a cured product has improved heat resistance; and at the same time, the heat resistance of the cured product will not be impaired because (B) does not behave as a plasticizer.

The component (C) in the present invention is an accelerator having at least one functional group selected from dimethylureido group, imidazole group, and tertiary amino group. Accelerators having a dimethylureido group [—NH—C(═O)—N(CH₃)₂], upon high-temperature heating, form isocyanate groups and dimethylamines, which activate epoxy groups of the component (A) and the curing agent of the component (B), accelerating curing. Accelerators having an imidazole group or a tertiary amino group have in its structure a nitrogen atom having an unshared electron pair, which activates epoxy groups of the component (A) and the curing agent of the component (B), accelerating curing. Such accelerators have high curing acceleration capability and provide an excellent pot life in a low-temperature range, and thus are used as the accelerator in the present invention.

Specific examples of the accelerator having a dimethylureido group, the component (C) in the present invention, include aliphatic dimethylurea in which dimethylureido groups are bound to aliphatics and aromatic dimethylurea in which dimethylureido groups are bound to aromatic rings.

Examples of the aliphatic dimethylurea that can used as the component (C) in the present invention include dimethylurea obtained from isophorone diisocyanate and dimethylamine, dimethylurea obtained from m-xylylene diisocyanate and dimethylamine, and dimethylurea obtained from hexamethylene diisocyanate and dimethylamine.

As the aromatic dimethylurea that can used as the component (C) in the present invention, phenyldimethylurea, methylenebis(phenyldimethylurea), tolylenebis(dimethylurea), and halogenated derivatives thereof are suitably used. Specific example thereof include 3-(3,4-dichlorophenyl)-1,1-dimethylurea, 3-phenyl-1,1-dimethylurea, 4,4′-methylenebis(phenyldimethylurea), 2,4-tolylenebis(1,1-dimethylurea), 3-(4-chlorophenyl)-1,1-dimethylurea, and 1,1-dimethyl-3-[3-(trifluoromethyl)phenyl]urea.

Among them, methylenebis(phenyldimethylurea) and tolylenebis(dimethylurea) which have particularly excellent curing acceleration capability and have no halogen atom that can cause circuit corrosion in its chemical structure, in particular, 4,4′-methylenebis(phenyldimethylurea) and 2,4-tolylenebis(1,1-dimethylurea) are preferably used.

Specific examples of the accelerator having an imidazole group, the component (C) in the present invention, include 2-methylimidazole, 2-ethyl-4-methylimidazole, 2-undecylimidazole, 2-heptadecylimidazole, 1,2-dimethylimidazole, 2-phenylimidazole, 2-phenyl-4-methylimidazole, 1-benzyl-2-phenylimidazole, 1-benzyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-cyanoethyl-2-ethyl-4-methylimidazolium trimellitate, 1-cyanoethyl-2-undecylimidazolium trimellitate, 1-cyanoethyl-2-phenylimidazolium trimellitate, 2,4-diamino-6-(2′-methylimidazolyl-(1′))-ethyl-s-triazine, 2,4-diamino-6-(2′-undecylimidazolyl-(1′))-ethyl-s-triazine, 2,4-diamino-6-(2′-ethyl-4-methylimidazolyl-(1′))-ethyl-s-triazine, 2,4-diamino-6-(2′methylimidazolyl-(1′))-ethyl-s-triazine/isocyanuric acid adduct, 2-phenylimidazole/isocyanuric acid adduct, 2-methylimidazole/isocyanuric acid adduct, 1-cyanoethyl-2-phenyl-4,5-di(2-cyanoethoxy)methylimidazole, 2-phenyl-4,5-dihydroxymethylimidazole, 2-phenyl-4-methyl-5-hydroxymethylimidazole, and imidazole adducts.

Specific examples of the accelerator having a tertiary amino group, the component (C) in the present invention, include N,N-dimethylpiperazine, N,N-dimethylaniline, triethylenediamine, N,N-dimethylbenzylamine, 2-(dimethylaminomethyl)phenol, 2,4,6-tris(dimethylaminomethyl)phenol, 1,8-diazabicyclo(5,4,0)undecene-7, and aliphatic tertiary amine adducts.

The component (C) is preferably contained in an amount of 1 to 5 parts by mass, more preferably 2 to 4 parts by mass, based on 100 parts by mass of the total amount of epoxy resin. When the amount of the component (C) is in this preferred range, curing does not require a high temperature, and at the same time, there is no possibility that the elasticity and heat resistance of a cured product are reduced.

The component (D) in the present invention may be any silica particles, and known silica particles can be used. In particular, spherical molten silica is suitably used because it reduces the viscosity of the resin composition.

The component (D) is contained in an amount of 60 to 85% by mass, preferably 65 to 80% by mass, in the whole resin composition. When the amount is more than 85% by mass, the viscosity of the resin composition is too high, which may result in failure of preparation. When it is less than 60% by mass, the linear expansion coefficient is high, thus failing to produce the effects of the present invention.

Further, the component (D) is preferably composed of a component d₁ with an average particle size of 10 μm to 100 μm and a component d₂ with an average particle size of 0.1 μm or more but less than 10 μm at a mass ratio (d₁/d₂) of 85/15 to 95/5, the average particle size being determined using a laser diffraction particle size analyzer. This allows the component d₂ to enter the space between particles of the component d₁, whereby the silica particles are introduced into the resin composition efficiently, and the linear expansion coefficient of a cured product is reduced to a low level even if the component (D) is not added in large amounts.

The component (E) in the present invention is a silane coupling agent and needs to be added in order to enhance the affinity of the component (D) for the resin. Specific examples of the component (E) in the present invention include epoxy silane, vinyl silane, styryl silane, methacrylic silane, acrylic silane, amino silane, allyl silane, ureido silane, mercapto silane, sulfide silane, and isocyanate silane.

Examples of epoxy silanes that can be used as the component (E) in the present invention include 3-glycidoxypropylmethyldimethoxysilane, 3-glycidoxypropylmethyldiethoxysilane, 3-glycidoxypropyltriethoxysilane, 3-glycidoxypropyltrimethoxysilane, and 2-(3,4-epoxycyclohexyl)ethyltrimethoxysilane.

Examples of vinyl silanes that can be used as the component (E) in the present invention include vinyltrimethoxysilane, vinyltriethoxysilane, and vinyltriacetoxysilane.

Examples of styryl silanes that can be used as the component (E) in the present invention include p-styryltrimethoxysilane.

Examples of methacrylic silanes that can be used as the component (E) in the present invention include 3-methacryloxypropyltriethoxysilane, 3-methacryloxypropylmethyldiethoxysilane, 3-methacryloxypropyltrimethoxysilane, and 3-methacryloxypropylmethyldimethoxysilane.

Examples of acrylic silanes that can be used as the component (E) in the present invention include 3-acryloxypropyltrimethoxysilane.

Examples of amino silanes that can be used as the component (E) in the present invention include N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, and N-phenyl-3-aminopropyltrimethoxysilane.

Examples of allyl silanes that can be used as the component (E) in the present invention include allyltrimethoxysilane.

Examples of ureido silanes that can be used as the component (E) in the present invention include 3-ureidopropyltriethoxysilane.

Examples of mercapto silanes that can be used as the component (E) in the present invention include 3-mercaptopropylmethyldimethoxysilane, 3-mercaptopropyltrimethoxysilane, and 3-mercaptopropyltriethoxysilane.

Examples of sulfide silanes that can be used as the component (E) in the present invention include bis(triethoxysilylpropyl)tetrasulfide.

Examples of isocyanate silanes that can be used as the component (E) in the present invention include 3-isocyanatepropyltriethoxysilane.

The component (E) is preferably contained in an amount of 0.5 to 2 parts by mass based on 100 parts by mass of the component (D). When the amount of the component (E) is in this preferred range, the affinity between the surface of the component (D) and the resin is enhanced, and the viscosity of the resin composition cannot be too high, which leads to easy preparation; and at the same time, the heat resistance of a cured product will not be impaired because the component (E) does not behave as a plasticizer.

It is necessary for the resin composition of the present invention to comprise the components (A) to (E), to be substantially free of solvent, and to be liquid at normal temperature. The resin composition being liquid at normal temperature means that the resin composition substantially has fluidity at 25° C. If the resin composition contains a solvent, many voids occur in a cured resin product formed by heating the resin composition, and a semiconductor packaging substrate tends to cause peeling or cracking. Further, if the resin composition is not liquid at normal temperature, the workability is impaired when the resin composition is applied to a metal sheet to produce a semiconductor packaging substrate.

The resin composition of the present invention must comprises the components (A) to (E) and may optionally comprise (F) the phosphorus-containing flame retardant. The flame-retardant effect of phosphorus atoms, which is believed to be due to the carbide formation-promoting effect of phosphorus atoms, is influenced by the phosphorus atom content in an epoxy resin composition. The amount of the component (F) is preferably such that phosphorus components in the resin composition are contained in an amount of 0.5 to 5% by mass in terms of phosphorus atom, more preferably 1.5 to 4% by mass, based on 100% by mass of the total amount of the components (A), (B), (C), and (F). When the amount is in this preferred range, a sufficient flame-retardant effect is produced, and at the same time, the heat resistance of a cured product will not be impaired because the flame retardant does not behave as a plasticizer. When a phosphorus-containing epoxy resin is used as the component (A), the total amount of phosphorus components derived from the component (A) and phosphorus components derived from the component (F) is preferably in the range described above.

Examples of the component (F) in the present invention include, but are not limited to, phosphazene compounds, monomeric phosphate esters, condensed phosphate esters, and phosphates.

The phosphazene compounds may be any compound as long as it has phosphazene structure in its molecule. “Phosphazene structure” as used herein refers to a structure represented by the formula: —P(R₂)═N— (wherein R is an organic group). Examples of phosphazene compounds that can be used as the component (F) include phosphonitrilic phenyl ester, hexamethoxycyclotriphosphazene, fluorinated cyclotriphosphazene, and cyclophosphazene.

Examples of monomeric phosphate esters that can be used as the component

(F) in the present invention include triphenyl phosphate, tricresyl phosphate, trixylyl phosphate, triethyl phosphate, cresyl diphenyl phosphate, xylyl diphenyl phosphate, cresyl bis(di-2,6-xylenyl)phosphate, 2-ethylhexyl diphenyl phosphate, tris(chloroethyl) phosphate, tris(chloropropyl) phosphate, tris(dichloropropyl) phosphate, tris(tribromopropyl) phosphate, and diethyl-N,N-bis(2-hydroxyethyl)aminomethyl phosphonate. Among them, triphenyl phosphate, tricresyl phosphate, trixylyl phosphate, triethyl phosphate, cresyl diphenyl phosphate, xylyl diphenyl phosphate, cresyl bis(di-2,6-xylenyl)phosphate, 2-ethylhexyl diphenyl phosphate, and diethyl-N,N-bis(2-hydroxyethyl)aminomethyl phosphonate, which have no halogen atom that can cause circuit corrosion in its chemical structure, are preferably used.

Examples of condensed phosphate esters that can be used as the component (F) in the present invention include resorcinol bis(diphenyl) phosphate, bisphenol A bis(diphenyl) phosphate, bisphenol A bis(dicresyl) phosphate, and resorcinol bis(di-2,6-xylenyl) phosphate.

Examples of phosphates that can be used as the component (F) in the present invention include ammonium polyphosphate and melamine polyphosphate.

Among the above, from the standpoint of both flame resistance and heat resistance, the component (F) in the present invention is preferably selected from phosphazene compounds or condensed phosphate esters. In particular, phosphazene compounds have a high phosphorus content per unit mass, and addition even in small amounts can produce excellent flame resistance.

The component (F) in the present invention may be dissolved or not dissolved but dispersed in the resin composition, and the component (F) may be used alone or used in combination of two or more.

In addition to the above-described components (A) to (F), other inorganic fillers and coupling agents are optionally added to the resin composition of the present invention, and additives, for example, flame retardants other than the component (F), coloring agents such as carbon black, mold releasing agents such as wax, and stress-lowering agents such as rubber may be further added. Examples of flame retardants other than the component (F) include dodecachlorododecahydro dimethanodibenzo cyclooctene, chlorendic acid, chlorendic anhydride, hexabromocyclodecane, tetrabromobisphenol A, bis(dibromopropyl) tetrabromobisphenol A, tris(dibromopropyl) isocyanurate, decabromodiphenyl oxide, bis(pentabromo)phenylethane, tris(tribromophenoxy)triazine, ethylenebistetrabromophthalimide, polybromophenylindane, tetrabromophthalate, bromophenol, tribromophenol, dibromo-m-cresol, dibromoneopentyl glycol, aluminum hydroxide, magnesium hydroxide, antimony trioxide, zinc sulfide, molybdenum compounds, tin compounds, zirconium oxide, silicone-based flame retardants, melamine cyanurate, and guanidine compounds.

For preparation of the resin composition of the present invention, a kneader, planetary mixer, triple roll mill, twin-screw extruder, or the like is preferably used. One example of preparation procedures for the resin composition will be described below, but this is not a limiting example. The components (A) to (E) and other additives are placed into a beaker, predispersed using a spatula, and then dispersed using a triple roll to thereby obtain a resin composition in which the components are uniformly dispersed.

One example of a semiconductor packaging substrate produced using the resin composition of the present invention will now be described, but the following method is not a limiting example.

The resin composition of the present invention is applied to a copper sheet and cured for use. The copper sheet is preliminarily provided with a bump pattern for connection to semiconductor parts. The pattern may be formed by any method, for example, etching. The thickness of the copper sheet is not critical; however, when it is too thick, many portions are wasted in the following steps, and when it is too thin, wrinkles can occur during resin application. Thus, it is preferably 100 to 500 μm.

The resin composition of the present invention is then applied to the copper sheet. The resin composition is preferably applied uniformly, and it may be applied by any method. Examples thereof include using a bar coater or vacuum printing in which the resin composition is applied under a vacuum environment, and to prevent formation of voids, it is preferable to use vacuum printing.

The copper sheet to which the resin composition of the present invention is applied is placed into a heating furnace to cure the resin. In this process, first, it is preferable, but not necessary, to perform leveling in which the copper sheet is maintained at a temperature at which the viscosity decreases but curing does not start for about 30 minutes to level the resin surface. The copper sheet is then cured at a temperature maintained at or higher than the temperature at which curing starts, held there for about 60 minutes, and then taken out of the heating furnace for cooling.

Subsequently, the resin surface is ground to the extent that the copper bump is exposed, and the copper sheet at the back is removed by a method such as etching to form a semiconductor packaging substrate with through copper vias.

The resin composition of the present invention can be cured at a relatively low temperature, and when it is applied to a copper thin film and molded, the copper sheet does not cause warpage because the linear expansion coefficient of a cured product is close to that of copper. Further, even if a substrate is bent, it does not cause cracking or peeling because of high elongation and high adhesiveness. Therefore, the resin composition of the present invention is preferably used for a semiconductor packaging substrate.

### EXAMPLES

The epoxy resin composition of the present invention will now be described in more detail by way of example.

### <Resin Material>

The following resin materials were used to produce the resin compositions in Examples.

### I. Epoxy Resin

“EPOTOHTO” (registered trademark) YD-128 (available from NIPPON STEEL & SUMIKIN CHEMICAL CO., LTD.): bisphenol A epoxy resin, epoxy equivalent weight: 189, the number of epoxy groups: 2

“EPICLON” (registered trademark) HP-4032D (available from DIC Corporation): epoxy resin having naphthalene structure, epoxy equivalent weight: 142, the number of epoxy groups: 2

“EPICLON” (registered trademark) HP-7200L (available from DIC Corporation): epoxy resin having dicyclopentadiene structure, epoxy equivalent weight: 245, the number of epoxy groups: 2.2 (80% or more of the number of epoxy groups: 2)

“jER” (registered trademark) YX4000 (available from Mitsubishi Chemical Corporation): epoxy resin having biphenyl structure, epoxy equivalent weight: 186, the number of epoxy groups: 2

ELM-434 (available from Sumitomo Chemical Co., Ltd.): glycidyl amine type epoxy resin, epoxy equivalent weight: 120, the number of epoxy groups: 4

FX-289Z-1 (available from Nippon Steel Chemical Co., Ltd.): epoxy resin comprising a phosphorus-containing epoxy resin obtained from diglycidyl ether of bisphenol A and DOPO, epoxy equivalent weight: 230, phosphorus content: 2%, the number of epoxy groups: 2

### II. Curing Agent

### [Amine Curing Agent (B)]

“jERCURE” (registered trademark) DICY7 (available from Mitsubishi Chemical Corporation): finely ground product of dicyandiamide (melting point: 210° C.)

ADH (available from Nippon Kasei Chemical Co., Ltd.): adipic acid dihydrazide (melting point: 180° C.)

[Curing Agent Other than (B)]

HN-5500 (available from Hitachi Chemical Co., Ltd.): methylhexahydrophthalic anhydride (liquid at normal temperature)

III. Accelerator (C) Having at Least One Functional Group Selected from Dimethylureido Group, Imidazole Group, and Tertiary Amino Group

“OMICURE” (registered trademark) 52 (available from PTI JAPAN LTD.): 4,4′-methylenebis(phenyldimethylurea)

“OMICURE” (registered trademark) 24 (available from PTI JAPAN LTD.): 2,4-tolylenebis(1,1-dimethylurea)

DCMU (available from HODOGAYA CHEMICAL CO., LTD.): 3-(3,4-dichlorophenyl)-1,1-dimethylurea

“CUREZOL” (registered trademark) 2PZ-CN (available from SHIKOKU CHEMICALS CORPORATION): 1-cyanoethyl-2-phenylimidazole

“AJICURE” (registered trademark) PN-23 (available from Ajinomoto Fine-Techno Co., Inc.): imidazole adduct

“AJICURE” (registered trademark) MY-24 (available from Ajinomoto Fine-Techno Co., Inc.): aliphatic tertiary amine adduct

### IV. Silica Particles (D)

FB-950 (available from DENKI KAGAKU KOGYO KABUSHIKI KAISHA): average particle size: 23.8 μm

SO-05 (available from Admatechs Company Limited): average particle size: 1.6 μm V. Silane coupling agent (E)

KBM-403 (available from Shin-Etsu Chemical Co., Ltd.): 3-glycidoxypropyltrimethoxysilane

### VI. Carbon Black

“TOKABLACK” (registered trademark) #7050 (available from Tokai Carbon Co., Ltd.)

### VII. Solvent

Methyl ethyl ketone (available from MARUZEN PETROCHEMICAL CO., LTD.)

### VIII. Flame Retardant

### [Phosphorus-Containing Flame Retardant (F)]

“Rabitle” (registered trademark) FP-110 (available from FUSHIMI Pharmaceutical Co., Ltd.): phosphazene compound, phosphonitrilic phenyl ester, phosphorus content: 13.4%

PX-200 (available from DAIHACHI CHEMICAL INDUSTRY CO., LTD.): condensed phosphate ester, resorcinol bis(di-2,6-xylenyl) phosphate, phosphorus content: 9.0%

TPP (available from DAIHACHI CHEMICAL INDUSTRY CO., LTD.): monomeric phosphate ester, triphenyl phosphate, phosphorus content: 9.5%

“MELAPUR” (registered trademark) 200 (available from BASF Japan Ltd.): phosphate, melamine polyphosphate, phosphorus content: 13%

### <Preparation of Epoxy Resin Composition>

The components were mixed at the composition ratios shown in Tables 1 to 6 using a triple roll mill to prepare an epoxy resin composition.

### <Measurement of Exothermic Peak Temperature of Resin Composition>

The exothermic peak of the resin composition was measured using a differential scanning calorimeter (DSC). Using an apparatus DSC Pyris 1 available from PerkinElmer Inc., 10 mg of the resin composition was placed into an aluminum pan (No. 0219-0062), and measurements were made from room temperature at a temperature rise rate of 10° C./min. The peak top temperature in a resulting exothermic chart was defined as an exothermic peak temperature.

### <Preparation of Cured Resin Plate>

At the bottom of a pressing device, a 2-mm-thick copper spacer with a cutout of a square with 50 mm sides was placed, and the temperature of the press was set at “exothermic peak temperature of resin composition+10° C.”. The resin composition was poured into the spacer, and the press was closed. After 20 minutes, the press was opened to obtain a cured resin plate.

### <Measurements of Glass Transition Temperature Tg of Cured Resin Plate>

A test piece 12.7 mm wide and 40 mm long was cut out from the cured resin plate, and a torsional DMA measurement was performed using a rheometer (ARES manufactured by TA Instruments). The measurement condition is a temperature rise rate of 5° C./min. The temperature at an inflection point of the storage modulus G′ obtained from the measurement was defined as Tg.

### <Measurements of Linear Expansion Coefficient of Cured Product>

A 5-mm square test piece was cut out from the cured resin plate, and its thermal expansion coefficient was measured using a thermo-mechanical analyzer (TMA). The upper and lower surfaces of the test piece were leveled in advance with waterproof abrasive paper #1500. Under a load of 0.05 N, measurements were made at a temperature rise rate of 5° C./min. A linear expansion coefficient was calculated from the average inclination in a range from 25 to 50° C. of a straight line obtained. The unit of the linear expansion coefficient of a cured product is μm/(m·° C.).

### <Evaluation of Flexural Properties of Substrate>

The resin composition was applied to a copper sheet (200 μm thick) of 70 mm×250 mm using a bar coater (No. 15 wire). The copper sheet was thermally cured for 1 hour in an oven set at “exothermic peak temperature of resin composition 10° C.” to obtain a substrate. The substrate was placed on a horizontal stand to observe the occurrence of warpage. At the longitudinal edge of the substrate, warpage of 10 mm or more from the surface of the stand was evaluated as bad, warpage of 5 to 10 mm as fair, and warpage of less than 5 mm as good.

The substrate was bent by pressing it against the side of a cylinder with a diameter of 20 cm, at which time the occurrence of cracking and peeling of a cured resin product was observed. For cracking, substrates with no cracking were evaluated as good, those with slight cracking as fair, and those with cracking as bad. For peeling, substrates with no peeling were evaluated as good, those with slight peeling as fair, and those with peeling as bad.

### <Evaluation of Flame Resistance>

The thermosetting resin composition of Examples 20 to 30 shown in Tables 5 and 6 was thermally cured for 1 hour in an oven set at “exothermic peak temperature of resin composition+10° C.” to obtain a cured product with a thickness of 0.5 mm. For Examples 21, 22, 23, and 31, a cured product with a thickness of 1 mm was obtained. Flame resistance was evaluated by a vertical flame test according to the UL94 standard. From the cured product formed, five test pieces 13 mm wide and 125 mm long was cut out. The height of the flame of a burner was adjusted to 19 mm. The center of the bottom of the test piece held upright was exposed to the flame for 10 seconds, and then separated from the flame to record burning time. After the fire went out, the test piece was immediately exposed to the burner flame for another 10 seconds and separated from the flame to measure burning time. Cases where there was no burning drip; time for the fire to go out was 10 seconds or less in both the first trial and the second trial; and the total burning time after five test pieces were exposed to flame ten times was 50 seconds or less were judged as V-0, and cases where the burning time was 30 seconds or less; and the total burning time after five test pieces were exposed to flame ten times was 250 seconds or less were judged as V-1. Cases where the burning time was the same as V-1 but there was a burning drip were judged as V-2, and cases where the burning time was longer than V-1 or where the fire spread to the holding portion of the test piece were judged as V-out.

### Examples 1 to 19

A resin composition was prepared as described above with the composition shown in Tables 1 to 3, and evaluated for exothermic peak temperature, glass transition temperature and linear expansion coefficient of a cured product, and flexural properties of a substrate.

As shown in Tables 1 to 3, the epoxy resin compositions of the present invention can be cured at a relatively low temperature because of their exothermic peak near 150° C., and can be cured at low energy without damaging electronic parts. Since their linear expansion coefficient is in the range close to that of copper, a substrate obtained by integral molding with a copper sheet causes less warpage. In addition, since the resin will not cause cracking or peeling even if the substrate is bent, substrates can be produced in high yield even when a continuous production process is used.

### Comparative Examples 1 to 7

An epoxy resin composition was prepared as described above with the composition shown in Table 4, and evaluated for exothermic peak temperature, glass transition temperature and linear expansion coefficient of a cured product, and flexural properties of a substrate.

As shown in Table 4, the epoxy resin compositions outside the scope of the present invention are not provided with satisfactory properties. First, in Comparative Example 1, since the component (C) was not contained, the exothermic peak temperature was high and molding at a higher temperature was required, and warpage and cracking occurred frequently. In Comparative Example 2, since the amount of the component (D) was small, the linear expansion coefficient was high, and a substrate caused significant warpage. In Comparative Example 3, since the component (D) was contained in excessive amounts, the viscosity during resin preparation was very high, and a resin composition could not be obtained. In Comparative Example 4, since an acid anhydride curing agent was used and the component (B) was not contained, the elongation and adhesiveness of the resin were insufficient, and cracking and peeling occurred frequently. In Comparative Example 5, since the component (E) was not contained, the adhesiveness of the resin to silica particles was insufficient, and cracking occurred frequently. In Comparative Example 6, since the amount of the bifunctional epoxy resin in the component (A) was small, the elongation of the resin was insufficient, and cracking and peeling occurred frequently. In Comparative Example 7, since a solvent was contained, many voids occurred in a cured resin product, and cracking and peeling occurred frequently.

### Example 20

A resin composition was prepared as described above with the composition shown in Tables 5 and 6 including the component (F) phosphorus-containing flame retardant, and evaluated for exothermic peak temperature, glass transition temperature and linear expansion coefficient of a cured product, flexural properties of a substrate, and flame resistance.

As the phosphorus-containing flame retardant (F), a phosphazene compound “Rabitle” (registered trademark) FP-110 was added in an amount of 0.6% by mass in terms of phosphorus content based on the resin components (composed of the component (A), the component (B), the component (C), and the component (F)). The Tg of a cured product and flexural properties of a substrate were satisfactory, and the flame resistance was at an acceptable level.

### Examples 21, 23, 25

An epoxy resin composition was prepared with an increased amount of “Rabitle” (registered trademark) FP-110 and evaluated. The flame resistance improved, and the Tg of a cured product and flexural properties of a substrate were at an acceptable level. Thus, substrates having high flame resistance can be produced in high yield even when a continuous production process is used.

### Examples 22, 24, 26

As the phosphorus-containing flame retardant (F), a condensed phosphate ester PX-200 was added as shown in Tables 5 and 6 to prepare an epoxy resin composition, which was evaluated. The flame resistance, Tg of a cured product, and flexural properties of a substrate were at an acceptable level. Thus, substrates having high flame resistance can be produced in high yield even when a continuous production process is used.

### Example 27

“Rabitle” (registered trademark) FP-110 was added in an amount of 4.7% by mass in terms of phosphorus content based on the resin components (composed of the component (A), the component (B), the component (C), and the component (F)) to prepare an epoxy resin composition, which was evaluated. High flame resistance and high flexural properties of a substrate were achieved, and the Tg of a cured product was low but at an acceptable level.

### Example 28

As the phosphorus-containing flame retardant (F), a monomeric phosphate ester TPP (triphenyl phosphate) was added in an amount of 2.1% by mass in terms of phosphorus content based on the resin components (composed of the component (A), the component (B), the component (C), and the component (F)) to prepare an epoxy resin composition, which was evaluated. The Tg of a cured product was low, but the flame resistance was high.

### Example 29

As the phosphorus-containing flame retardant (F), a phosphate “MELAPUR” (registered trademark) 200 was added in an amount of 2.1% by mass in terms of phosphorus content based on the resin components (composed of the component (A), the component (B), the component (C), and the component (F)) to prepare an epoxy resin composition, which was evaluated. Slight warpage of a copper sheet was observed and the flame resistance was low, but the Tg of a cured product was within the allowable range.

### Example 30

As the epoxy resin (A), a phosphorus-containing epoxy resin FX-289Z-1 was added in an amount of 1.5% by mass in terms of phosphorus content based on the resin components (composed of the component (A), the component (B), the component (C), and the component (F)) to prepare an epoxy resin composition, which was evaluated. The Tg of a cured product was slightly low, but the flame resistance was high.

TABLE 1

| (Unit) | | | | | Example 1 | Example 2 | Example 3 | Example 4 | Example 5 | Example 6 | Example 7 |
|---|---|---|---|---|---|---|---|---|---|---|---|
| Epoxy | (A) | Parts by mass based on | YD128 | | 100 | 60 | 50 | 60 | 50 | 60 | 65 |
| resin | Epoxy resin | 100 parts by mass of | HP-4032D | | | 40 | 50 | | 50 | | |
| com- | | the total amount of | HP-7200L | | | | | | | 40 | 35 |
| position | | component (A) | YX4000 | | | | | 40 | | | |
| | | | ELM-434 | | | | | | | | |
| | (B) | Parts by mass based on | DICY7 | | 6 | 7 | 7 | 6 | 7 | | |
| | Amine | 100 parts by mass of | ADH | | | | | | | 22 | 22 |
| | curing agent | component (A) | | | | | | | | | |
| | Other curing | Parts by mass based on | HN-5500 | | | | | | | | |
| | agent | 100 parts by mass of | | | | | | | | | |
| | | component (A) | | | | | | | | | |
| | (C) | Parts by mass based on | OMICURE 52 | | | | | | | | |
| | Accelerator | 100 parts by mass of | OM1CURE 24 | | 3 | 3 | 3 | | | | |
| | | component (A) | DCMU | | | | | 4 | 5 | | |
| | | | CUREZOL | | | | | | | 5 | |
| | | | 2PZ-CN | | | | | | | | |
| | | | AJICURE PN-23 | | | | | | | | 4 |
| | | | AJICURE MY-24 | | | | | | | | |
| | (D) | Parts by mass based on | d₁ | FB-950 | 315 | 315 | 315 | 241 | 315 | 310 | 321 |
| | Silica | 100 parts by mass of | d₂ | SO-C5 | 35 | 35 | 35 | 43 | 35 | 16 | 36 |
| | particles | component (A) | | | | | | | | | |

| | | | | | | | | | |
|---|---|---|---|---|---|---|---|---|---|
| (E) Silane | Parts by mass based on | KBM-403 | 0.6 | 0.6 | 0.6 | 0.7 | 0.6 | 0.7 | 0.6 |
| coupling | 100 parts by mass of | | | | | | | | |
| agent | component (D) | | | | | | | | |
| Carbon black | % by mass based on | #7050 | 0.3 | 0.3 | 0.3 | 0.3 | 0.3 | 0.3 | 0.3 |
| | the total amount of | | | | | | | | |
| | resin composition | | | | | | | | |

| The amount of component (D) based on the total amount of | | 76 | 76 | 76 | 72 | 76 | 72 | 74 |
|---|---|---|---|---|---|---|---|---|
| resin composition (% by mass) | | | | | | | | |
| d₁/d₂ in component (D) (mass ratio) | | 90/10 | 90/10 | 90/10 | 85/15 | 90/10 | 95/5 | 90/10 |
| Physical properties of resin composition | Exothermic peak | 149 | 147 | 146 | 145 | 153 | 152 | 143 |
| and cured product | temperature of | | | | | | | |
| | composition | | | | | | | |
| | (° C.) | | | | | | | |
| | Linear expansion | 17 | 14 | 12 | 15 | 12 | 17 | 16 |
| | coefficient of | | | | | | | |
| | cured product | | | | | | | |
| | (μm/(m · ° C.)) | | | | | | | |
| | Tg of cured | 125 | 146 | 151 | 164 | 149 | 151 | 149 |
| | product (° C.) | | | | | | | |
| Flexural properties of substrate | Warpage | good | good | good | good | good | good | good |
| | Cracking | good | good | good | good | good | good | good |
| | Peeling | good | good | good | good | good | good | good |

TABLE 2

| | | | | | | | Example | Example | Example | Example |
|---|---|---|---|---|---|---|---|---|---|---|
| (Unit) | | | | | Example 8 | Example 9 | 10 | 11 | 12 | 13 |
| Epoxy | (A) | Parts by mass based on | YD128 | | 70 | 50 | 50 | 50 | 50 | 50 |
| resin | Epoxy resin | 100 parts by mass of the | HP-4032D | | | 50 | 50 | 50 | 50 | 50 |
| composition | | total amount of | HP-7200L | | 30 | | | | | |
| | | component (A) | YX4000 | | | | | | | |
| | | | ELM-434 | | | | | | | |
| | (B) | Parts by mass based on | DICY7 | | | 7 | 7 | 7 | 7 | 7 |
| | Amine curing | 100 parts by mass of | ADH | | 22 | | | | | |
| | agent | component (A) | | | | | | | | |
| | Other curing | Parts by mass based on | HN-5500 | | | | | | | |
| | agent | 100 parts by mass of | | | | | | | | |
| | | component (A) | | | | | | | | |
| | (C) | Parts by mass based on | OMICURE 52 | | | | | | | |
| | Accelerator | 100 parts by mass of | OMICURE 24 | | | 3 | 3 | 3 | 3 | 3 |
| | | component (A) | DCMU | | | | | | | |
| | | | CUREZOL 2PZ-CN | | | | | | | |
| | | | AJICURE PN-23 | | | | | | | |
| | | | AJICURE MY-24 | | | 4 | | | | |
| | (D) | Parts by mass based on | d₁ | FB-950 | 303 | 148 | 561 | 298 | 250 | 280 |
| | Silica particles | 100 parts by mass of | d₂ | SO-C5 | 54 | 17 | 62 | 52 | 13 | 70 |
| | | component (A) | | | | | | | | |

| | | | | | | | | |
|---|---|---|---|---|---|---|---|---|
| (E) Silane | Parts by mass based on | KBM-403 | 0.6 | 0.6 | 0.6 | 0.6 | 0.6 | 0.6 |
| coupling agent | 100 parts by mass of | | | | | | | |
| | component (D) | | | | | | | |
| Carbon black | % by mass based on the | #7050 | 0.3 | 0.3 | 0.3 | 0.3 | 0.3 | 0.3 |
| | total amount of resin | | | | | | | |
| | composition | | | | | | | |

| The amount of component (D) based on the total amount of | | 74 | 60 | 85 | 76 | 70 | 75 |
|---|---|---|---|---|---|---|---|
| resin composition (% by mass) | | | | | | | |
| d₁/d₂ in component (D) (mass ratio) | | 85/15 | 90/10 | 90/10 | 85/15 | 95/5 | 80/20 |
| Physical properties of resin composition and cured | Exothermic peak | 146 | 146 | 146 | 146 | 147 | 146 |
| product | temperature of | | | | | | |
| | composition (° C.) | | | | | | |
| | Linear expansion | 15 | 23 | 6 | 11 | 19 | 9 |
| | coefficient of cured | | | | | | |
| | product (μm/ | | | | | | |
| | (m · ° C.)) | | | | | | |
| | Tg of cured | 147 | 150 | 150 | 151 | 151 | 149 |
| | product (° C.) | | | | | | |
| Flexural properties of substrate | Warpage | good | fair | fair | good | good | fair |
| | Cracking | good | good | fair | good | good | good |
| | Peeling | good | good | good | good | good | good |

TABLE 3

| | | | | | Example | Example | Example | Example | Example | Example |
|---|---|---|---|---|---|---|---|---|---|---|
| (Unit) | | | | | 14 | 15 | 16 | 17 | 18 | 19 |
| Epoxy resin | (A) | Parts by mass based on | YD128 | | 50 | | | 70 | 80 | 80 |
| composition | Epoxy resin | 100 parts by mass of the | HP-4032D | | 50 | 50 | 50 | 30 | | |
| | | total amount of | HP-7200L | | | 50 | | | | |
| | | component (A) | YX4000 | | | | 50 | | | |
| | | | ELM-434 | | | | | | 20 | 20 |
| | (B) | Parts by mass based on | DICY7 | | 7 | 7 | 8 | 7 | 7 | 7 |
| | Amine curing | 100 parts by mass of | ADH | | | | | | | |
| | agent | component (A) | | | | | | | | |
| | Other curing | Parts by mass based on | HN-5500 | | | | | | | |
| | agent | 100 parts by mass of | | | | | | | | |
| | | component (A) | | | | | | | | |
| | (C) | Parts by mass based on | OMICURE 52 | | | 5 | 5 | 5 | 5 | 7 |
| | Accelerator | 100 parts by mass of | OMICURE 24 | | 3 | | | | | |
| | | component (A) | DCMU | | | | | | | |
| | | | CUREZOL 2PZ-CN | | | | | | | |
| | | | AJICURE PN-23 | | | | | | | |
| | | | AJICURE MY-24 | | | | | | | |
| | (D) | Parts by mass based on | d₁ | FB-950 | 260 | 230 | 230 | 315 | 315 | 315 |
| | Silica particles | 100 parts by mass of | d₂ | SO-C5 | | 25 | 25 | 35 | 35 | 35 |
| | | component (A) | | | | | | | | |

| | | | | | | | | |
|---|---|---|---|---|---|---|---|---|
| (E) Silane | Parts by mass based on | KBM-403 | 0.6 | 0.6 | 0.6 | 0.6 | 0.6 | 0.6 |
| coupling | 100 parts by mass of | | | | | | | |
| agent | component (D) | | | | | | | |
| Carbon black | % by mass based on the | #7050 | 0.3 | 0.3 | 0.3 | 0.3 | 0.3 | 0.3 |
| | total amount of resin | | | | | | | |
| | composition | | | | | | | |
| Methyl ethyl | % by mass based on the | | | | | | | |
| ketone | total amount of resin | | | | | | | |
| | composition | | | | | | | |

| The amount of component (D) based on the total amount of resin | | 70 | 70 | 70 | 76 | 76 | 75 |
|---|---|---|---|---|---|---|---|
| composition (% by mass) | | | | | | | |
| d₁/d₂ in component (D) (mass ratio) | | 100/0 | 90/10 | 90/10 | 90/10 | 90/10 | 90/10 |
| Physical properties of resin composition and cured | Exothermic peak | 146 | 146 | 147 | 147 | 146 | 142 |
| product | temperature of | | | | | | |
| | composition (° C.) | | | | | | |
| | Linear expansion | 22 | 17 | 16 | 15 | 15 | 17 |
| | coefficient of cured | | | | | | |
| | product (μm/ | | | | | | |
| | (m · ° C.)) | | | | | | |
| | Tg of cured | 149 | 183 | 153 | 142 | 150 | 139 |
| | product (° C.) | | | | | | |
| Flexural properties of substrate | Warpage | fair | good | good | good | good | good |
| | Cracking | good | good | good | good | good | fair |
| | Peeling | good | good | good | good | good | good |

TABLE 4

| | | | | | Comparative | Comparative | Comparative | Comparative | Comparative | Comparative | Comparative |
|---|---|---|---|---|---|---|---|---|---|---|---|
| (Unit) | | | | | Example 1 | Example 2 | Example 3 | Example 4 | Example 5 | Example 6 | Example 7 |
| Epoxy resin composition | (A) | Parts by mass based on | YD128 | | 50 | 50 | 50 | 50 | 50 | 40 | |
| | Epoxy resin | 100 parts by mass of the | HP-4032D | | 50 | 50 | 50 | 50 | 50 | | 50 |
| | | total amount of | HP-7200L | | | | | | | | 50 |
| | | component (A) | YX4000 | | | | | | | | |
| | | | ELM-434 | | | | | | | 60 | |
| | (B) | Parts by mass based on | DICY7 | | 7 | 7 | 7 | | 7 | 8 | 7 |
| | Amine curing agent | 100 parts by mass of | ADH | | | | | | | | |
| | | component (A) | | | | | | | | | |
| | Other curing agent | Parts by mass based on | HN-5500 | | | | | 100 | | | |
| | | 100 parts by mass of | | | | | | | | | |
| | (C) | by mass based on | OMICURE 52 | | | | | | | 5 | |
| | Accelerator | 100 parts by mass of | OMICURE 24 | | | 3 | 3 | 3 | 3 | | |
| | | component (A) | DCMU | | | | | | | | 4 |
| | | | CUREZOL 2PZ-CN | | | | | | | | |
| | | | AJICURE PN-23 | | | | | | | | |
| | | | AJICURE MY-24 | | | | | | | | |
| | (D) | Parts by mass based on | d₁ | FB-950 | 315 | 121 | 891 | 550 | 315 | 315 | 241 |
| | Silica particles | 100 parts by mass of | d₂ | SO-C5 | 35 | 13 | 99 | 61 | 35 | 35 | 43 |
| | | component (A) | | | | | | | | | |

| | | | | | | | | | |
|---|---|---|---|---|---|---|---|---|---|
| (E) Silane coupling | Parts by mass based on | KBM-403 | 0.6 | 0.6 | 0.6 | 0.6 | | 0.6 | 0.7 |
| agent | 100 parts by mass of | | | | | | | | |
| | component (D) | | | | | | | | |
| Carbon black | % by mass based on the | #7050 | 0.3 | 0.3 | 0.3 | 0.3 | 0.3 | 0.3 | 0.3 |
| | total amount of resin | | | | | | | | |
| Methyl ethyl ketone | % by mass based on the | | | | | | | | 2.0 |
| | total amount of resin | | | | | | | | |
| | composition | | | | | | | | |

| The amount of component (D) based on the total amount of resin | | 77 | 55 | 90 | 75 | 76 | 75 | 70 |
|---|---|---|---|---|---|---|---|---|
| composition (% by mass) | | | | | | | | |
| d₁/d₂ in component (D) (mass ratio) | | 90/10 | 90/10 | 90/10 | 90/10 | 90/10 | 90/10 | 85/15 |
| Physical properties of resin composition and cured | Exothermic peak | 197 | 146 | — | 132 | 147 | 146 | 144 |
| product | temperature of | | | | | | | |
| | composition (° C.) | | | | | | | |
| | Linear expansion | 14 | 28 | — | 13 | 12 | 17 | 17 |
| | coefficient of cured | | | | | | | |
| | product (μm/(m · ° C.)) | | | | | | | |
| | Tg of cured product (° C.) | 140 | 149 | — | 125 | 152 | 158 | 179 |
| Flexural properties of substrate | Warpage | fair | bad | — | fair | good | good | good |
| | Cracking | bad | good | — | bad | bad | bad | bad |
| | Peeling | fair | good | — | bad | fair | bad | bad |

TABLE 5

| | | | | | Example | Example | Example | Example | Example | Example |
|---|---|---|---|---|---|---|---|---|---|---|
| (Unit) | | | | | 20 | 21 | 22 | 23 | 24 | 25 |
| Epoxy | (A) | Parts by mass based on | YD128 | | 60 | 60 | 70 | 60 | 70 | 60 |
| resin | Epoxy resin | 100 parts by mass of the | HP-4032D | | 40 | 40 | | 40 | | 40 |
| composition | | total amount of | HP-7200L | | | | 30 | | 30 | |
| | | component (A) | FX-289Z-1 | | | | | | | |
| | (B) | Parts by mass based on | DICY7 | | 7 | 7 | | 7 | | 7 |
| | Amine curing | 100 parts by mass of | ADH | | | | 22 | | 22 | |
| | agent | component (A) | | | | | | | | |
| | (C) | Parts by mass based on | OMICURE 52 | | | 5 | | | | 5 |
| | Accelerator | 100 parts by mass of | OMICURE 24 | | 3 | | | 3 | | |
| | | component (A) | CUREZOL | | | | | | | |
| | | 2PZ-CN | | | | | | | | |
| | | | AJICURE PN-23 | | | | | | | |
| | | | AJICURE MY-24 | | | | 4 | | 4 | |
| | (D) | Parts by mass based on | d₁ | FB-950 | 415 | 261 | 386 | 274 | 422 | 330 |
| | Silica particles | 100 parts by mass of | d₂ | SO-C5 | 46 | 29 | 68 | 30 | 74 | 37 |
| | | component (A) | | | | | | | | |

| | | | | | | | | |
|---|---|---|---|---|---|---|---|---|
| (E) Silane | Parts by mass based on | KBM-403 | 0.6 | 0.6 | 0.6 | 0.6 | 0.6 | 0.6 |
| coupling | 100 parts by mass of | | | | | | | |
| agent | component (D) | | | | | | | |
| Carbon black | % by mass based on the | #7050 | 0.3 | 0.3 | 0.3 | 0.3 | 0.3 | 0.3 |
| | total amount of resin | | | | | | | |
| | composition | | | | | | | |
| (F) Phosphorus- | Parts by mass based on | FP-110 | 5 | 14 | | 20 | | 46 |
| containing flame | 100 parts by mass of | PX-200 | | | 25 | | 38 | |
| retardant | component (A) | TPP | | | | | | |
| | | MELAPUR 200 | | | | | | |

| The amount of component (D) based on the total amount of resin composition | | 80 | 70 | 75 | 70 | 75 | 70 |
|---|---|---|---|---|---|---|---|
| (% by mass) | | | | | | | |
| d₁/d₂ in component (D) (mass ratio) | | 90/10 | 90/10 | 85/15 | 90/10 | 85/15 | 90/10 |
| Phosphorus components based on resin components | | 0.6 | 1.5 | 1.5 | 2.1 | 2.1 | 3.9 |
| ((A) + (B) + (C) + (F)) (% by mass) | | | | | | | |
| Physical properties of resin composition and cured | Exothermic peak | 146 | 146 | 145 | 147 | 145 | 146 |
| product | temperature of | | | | | | |
| | composition | | | | | | |
| | (° C.) | | | | | | |
| | Linear expansion | 11 | 17 | 13 | 18 | 15 | 18 |
| | coefficient of | | | | | | |
| | cured product | | | | | | |
| | (μm/(m · ° C.)) | | | | | | |
| | Tg of cured | 144 | 138 | 141 | 136 | 129 | 121 |
| | product (° C.) | | | | | | |
| Flexural properties of substrate | Warpage | good | good | good | good | good | good |
| | Cracking | good | good | good | good | good | good |
| | Peeling | good | good | good | good | good | good |
| Flame resistance | UL-94 Standard | *V-1 | *V-0 | *V-0 | V-0 | V-0 | V-0 |
| | (0.5 mm) | | | | | | |

*Measured with 1-mm-thick plate

TABLE 6

| | | | | | Example | Example | Example | Example | Example |
|---|---|---|---|---|---|---|---|---|---|
| (Unit) | | | | | 26 | 27 | 28 | 29 | 30 |
| Epoxy | (A) | Parts by mass based on | YD128 | | 70 | 60 | 50 | 50 | |
| resin | Epoxy resin | 100 parts by mass of the | HP-4032D | | | 40 | 50 | 50 | 20 |
| composition | | total amount of | HP-7200L | | 30 | | | | |
| | | component (A) | FX-289Z-1 | | | | | | 80 |
| | (B) | Parts by mass based on | DICY7 | | | 7 | 7 | 7 | 6 |
| | Amine curing agent | 100 parts by mass of | ADH | | 22 | | | | |
| | | component (A) | | | | | | | |
| | (C) | Parts by mass based on | OMICURE 52 | | | 5 | | | |
| | Accelerator | 100 parts by mass of | OMICURE 24 | | | | | | |
| | | component (A) | CUREZOL 2PZ-CN | | | | | | 3 |
| | | | AJICURE PN-23 | | | | | 3 | |
| | | | AJICURE MY-24 | | 4 | | 3 | | |
| | (D) | Parts by mass based on | d₁ | FB-950 | 282 | 305 | 282 | 260 | 415 |
| | Silica particles | 100 parts by mass of | d₂ | SO-C5 | 71 | 16 | 50 | 46 | 22 |
| | | component (A) | | | | | | | |

| | | | | | | | |
|---|---|---|---|---|---|---|---|
| (E) Silane coupling | Parts by mass based on | KBM-403 | 0.6 | 0.6 | 0.6 | 0.6 | 0.6 |
| agent | 100 parts by mass of | | | | | | |
| | component (D) | | | | | | |
| Carbon black | % by mass based on the | #7050 | 0.3 | 0.3 | 0.3 | 0.3 | 0.3 |
| | total amount of resin | | | | | | |
| | composition | | | | | | |
| (F) Phosphorus- | Parts by mass based on | FP-110 | | 60 | | | |
| containing flame | 100 parts by mass of | PX-200 | 63 | | | | |
| retardant | component (A) | TPP | | | 32 | | |
| | | MELAPUR 200 | | | | 21 | |

| The amount of component (D) based on the total amount of resin composition | | 65 | 65 | 70 | 70 | 80 |
|---|---|---|---|---|---|---|
| (% by mass) | | | | | | |
| d₁/d₂ in component (D) (mass ratio) | | 80/20 | 95/5 | 85/15 | 85/15 | 95/5 |
| Phosphorus components based on resin components | | 3.0 | 4.7 | 2.1 | 2.1 | 1.5 |
| ((A) + (B) + (C) + (F)) (% by mass) | | | | | | |
| Physical properties of resin composition and cured | Exothermic peak | 146 | 145 | 144 | 150 | 150 |
| product | temperature of | | | | | |
| | composition (° C.) | | | | | |
| | Linear expansion | 20 | 19 | 20 | 18 | 14 |
| | coefficient of cured | | | | | |
| | product (μm/(m · ° C.)) | | | | | |
| | Tg of cured product (° C.) | 120 | 112 | 112 | 125 | 118 |
| Flexural properties of substrate | Warpage | good | good | fair | fair | good |
| | Cracking | good | good | good | fair | good |
| | Peeling | good | good | fair | good | fair |
| Flame resistance | UL-94 Standard (0.5 mm) | V-0 | V-0 | V-0 | V-1 | *V-0 |

*Measured with 1-mm-thick plate

As described above, the resin composition of the present invention can be cured at a relatively low temperature, and when it is applied to a copper thin film and molded, the copper sheet does not cause warpage because the linear expansion coefficient of a cured product is close to that of copper. Further, even if a substrate is bent, it does not cause cracking or peeling because of high elongation and high adhesiveness. Therefore, the resin composition of the present invention is preferably used for a semiconductor packaging substrate.

### INDUSTRIAL APPLICABILITY

The resin composition of the present invention can be cured at a relatively low temperature, and when it is applied to a copper thin film and molded, the copper sheet does not cause warpage because the linear expansion coefficient of a cured product is close to that of copper. Further, even if a substrate is bent, it does not cause cracking or peeling because of high elongation and high adhesiveness. Therefore, the resin composition of the present invention provides a semiconductor packaging substrate with high productivity. It is expected that this leads particularly to reduction in cost of electronic equipment manufacturing and reduction of environment load.

1.-13. (canceled)

14. A resin composition, comprising the following components (A) to (E):
(A) an epoxy resin having at least one chemical structure selected from naphthalene structure, biphenyl structure, and dicyclopentadiene structure;
(B) an amine curing agent;
(C) an accelerator having at least one functional group selected from dimethylureido group, imidazole group, and tertiary amino group;
(D) silica particles; and
(E) a silane coupling agent,
wherein the epoxy resin (A) comprises 80 to 100% by mass of a bifunctional epoxy resin, and (D) is contained in an amount of 60 to 85% by mass based on 100% by mass of the total amount of the resin composition, the resin composition being substantially free of solvent and liquid at normal temperature.

15. The resin composition according to claim 14, further comprising (F) a phosphorus-containing flame retardant.

16. The resin composition according to claim 14, wherein the amine curing agent (B) is an aliphatic amine curing agent.

17. The resin composition according to claim 14, wherein the amine curing agent (B) is dicyandiamide or a derivative thereof.

18. The resin composition according to claim 14 wherein the accelerator (C) having at least one functional group selected from dimethylureido group, imidazole group, and tertiary amino group is at least one compound selected from phenyldimethylurea, methylenebis(phenyldimethylurea), tolylenebis(dimethylurea), and halogenated derivatives thereof.

19. The resin composition according to claim 14, wherein the accelerator (C) having at least one functional group selected from dimethylureido group, imidazole group, and tertiary amino group is methylenebis(phenyldimethylurea) or tolylenebis(dimethylurea).

20. The resin composition according to claim 14, wherein the silica particles (D) comprise a component d₁ with an average particle size of 10 μm to 100 μm and a component d₂ with an average particle size of 0.1 μm or more but less than 10 μm at a mass ratio (d₁/d₂) of 85/15 to 95/5, the average particle size being determined using a laser diffraction particle size analyzer.

21. The resin composition according to claim 14, wherein the silane coupling agent (E) is contained in an amount of 0.5 to 2 parts by mass based on 100 parts by mass of the silica particles (D).

22. The resin composition according to claim 15, wherein phosphorus components in the resin composition are contained in an amount of 0.5 to 5% by mass in terms of phosphorus atom based on 100% by mass of the total amount of the components (A), (B), (C), and (F).

23. The resin composition according to claim 15, wherein the phosphorus-containing flame retardant (F) is selected from phosphazene compounds and condensed phosphate esters.

24. A molded product produced by molding the resin composition according to claim 14.

25. A semiconductor packaging substrate produced by applying the resin composition according to claim 14 to a metal sheet and curing the metal sheet.
